(19) United States
(12) Patent Application Publication
(10) Pub. No.: US 2025/0095578 A1
(43) Pub. Date: Mar. 20, 2025

(54) OLED DISPLAY PANEL

(71) Applicant: WUHAN CHINA STAR OPTOELECTRONICS SEMICONDUCTOR DISPLAY TECHNOLOGY CO., LTD., Wuhan (CN)

(72) Inventors: Wei WANG, Wuhan (CN); Qing HUANG, Wuhan (CN)

(73) Assignee: WUHAN CHINA STAR OPTOELECTRONICS SEMICONDUCTOR DISPLAY TECHNOLOGY CO., LTD., Wuhan (CN)

(21) Appl. No.: 18/964,295

(22) Filed: Nov. 29, 2024

Related U.S. Application Data
(63) Continuation of application No. 17/758,135, filed on Jun. 29, 2022, now Pat. No. 12,198,620.

(30) Foreign Application Priority Data
Apr. 14, 2022 (CN) 202210413579.9

(51) Int. Cl. G09G 3/3233; H10K 59/121; H10K 59/35

(52) U.S. Cl. CPC G09G 3/3233; H10K 59/1216; H10K 59/35; G09G 2300/0426; G09G 2300/0452; G09G 2300/0819; G09G 2300/0852; G09G 2320/02

(57) ABSTRACT

The present disclosure provides an OLED display panel, including: a first conductive channel layer including active layers of a first transistor and a second transistor; a first gate layer disposed on the first conductive channel layer and including gates of the first and second transistors, a first electrode plate of a first capacitor, and a first end of the second capacitor; a second gate layer disposed on the first gate layer and including a second end of the second capacitor; a second conductive channel layer disposed on the second gate layer and including a second electrode plate of the first capacitor; a source and drain layer disposed on the first gate layer and including sources and drains of the first and second transistors; and a light emitting device disposed on the source and drain layer. The first transistor is configured to control a current flowing through the light-emitting device.

### CROSS-REFERENCE TO RELATED APPLICATIONS

This application is a continuation in part application of U.S. patent application Ser. No. 17/758,135, filed on Jun. 29, 2022, which is a US national phase application based upon an International Application No. PCT/CN2022/092729, filed on May 13, 2022, which claims priority to Chinese Patent Application No. 202210413579.9, filed on Apr. 14, 2022. The disclosures of the aforementioned applications are incorporated herein by reference in their entireties.

### TECHNICAL FIELD

The present application relates to the technical field of display, and especially to an OLED display panel.

### BACKGROUND

An organic light emitting diode (OLED) display panel includes a plurality of sub-pixels, and the plurality of sub-pixels include red sub-pixels, green sub-pixels, and blue sub-pixels. Each sub-pixel is driven by a sub-pixel circuit, and the sub-pixel circuit is configured to drive a light-emitting device to emit light. Because efficiency and turn-on voltages of the red sub-pixels, the green sub-pixels, and the blue sub-pixels are different, the green sub-pixels are prone to a light leakage phenomenon under a black screen, while the blue sub-pixels do not easily reach preset brightness under a high brightness screen. Based on this, the red sub-pixels, the green sub-pixels, and the blue sub-pixels display nonuniformly in existing OLED display panels.

### SUMMARY

The present disclosure provides an OLED display panel. The OLED display panel includes: a substrate; a first conductive channel layer disposed on the substrate, and including an active layer of a first transistor and an active layer of a second transistor; a first gate layer disposed on one side of the first conductive channel layer facing away from the substrate, and including a gate of the first transistor, a gate of the second transistor, a first electrode plate of a first capacitor, and a first end of the second capacitor; a second gate layer disposed on one side of the first gate layer facing away from the substrate, and including a second end of the second capacitor; a second conductive channel layer disposed on one side of the second gate layer facing away from the substrate, and including a second electrode plate of the first capacitor; a source and drain layer disposed on one side of the first gate layer facing away from the substrate, and including a source and a drain of the first transistor, and a source and a drain of the second transistor; and a light emitting device disposed on one side of the source and drain layer facing away from the substrate. The first transistor is configured to control a current flowing through the light-emitting device.

### BRIEF DESCRIPTION OF THE DRAWINGS

In order to more clearly illustrate technical solutions in embodiments of the present application, accompanying drawings that need to be used in the description of the embodiments will be briefly introduced below. Obviously, the drawings in the following description are only some embodiments of the present application, for those skilled in the art, other drawings can also be obtained from these drawings without creative effort.

FIG. 1 is a schematic circuit diagram of a sub-pixel circuit of an OLED display panel provided by an embodiment of the present application.

FIG. 2 is a schematic illustration diagram of a first capacitor affecting light emission of a light-emitting device.

FIG. 3 is a first schematic illustration diagram of potentials of first nodes corresponding to a red sub-pixel circuit, a green sub-pixel circuit, and a blue sub-pixel circuit in the OLED display panel provided by an embodiment of the present application.

FIG. 4 is a second schematic illustration diagram of the potentials of the first nodes corresponding to the red sub-pixel circuit, the green sub-pixel circuit, and the blue sub-pixel circuit in the OLED display panel provided by an embodiment of the present application.

FIG. 5 is a third schematic illustration diagram of the potentials of the first nodes corresponding to the red sub-pixel circuit, the green sub-pixel circuit, and the blue sub-pixel circuit in the OLED display panel provided by an embodiment of the present application.

FIG. 6 is a schematic structural diagram of the first capacitor in the sub-pixel circuit shown in FIG. 1.

FIG. 7 is a schematic structural diagram of the OLED display panel provided by an embodiment of the present application.

FIG. 8 is a schematic diagram of wiring of the sub-pixel circuit shown in FIG. 1.

### DETAILED DESCRIPTION

The technical solutions in the embodiments of the present application will be clearly and completely described below with reference to the drawings in the embodiments of the present application. Obviously, the described embodiments are only a part of the embodiments of the present application, but not all of the embodiments. Based on the embodiments in the present application, all other embodiments obtained by those skilled in the art without creative work fall within the protection scope of the present application.

In addition, terms “first”, “second”, “third”, “fourth”, “fifth”, “sixth”, “seventh” in the description and claims of the present application and the above-mentioned drawings etc. are used to distinguish different objects, not to describe specific order. The terms “comprising”, “having” and any variations thereof are intended to cover non-exclusive inclusion.

It should be noted that, since a source and a drain of a transistor used in the present application are symmetrical, the source and the drain thereof are interchangeable. In the embodiments of the present application, in order to distinguish two electrodes of the transistor except for a gate, one electrode is called the source, and another one electrode is called the drain.

An OLED display panel provided by the embodiment of the present application includes a plurality of sub-pixels. Each sub-pixel includes a light-emitting device. Each sub-pixel is driven by a sub-pixel circuit. The sub-pixel circuit is configured to drive the light-emitting device to emit light. The plurality of sub-pixels include red sub-pixels, green sub-pixels, and blue sub-pixels. The red sub-pixel includes a red light-emitting device, the green sub-pixel includes a green light-emitting device, and the blue sub-pixel includes a blue light-emitting device. The red sub-pixel is driven by the red sub-pixel circuit, the green sub-pixel is driven by the green sub-pixel circuit, and the blue sub-pixel is driven by the blue sub-pixel circuit. The red sub-pixel circuit is configured to drive the red light-emitting device to emit light. The green sub-pixel circuit is configured to drive the green light-emitting device to emit light. The blue sub-pixel circuit is configured to drive the blue light-emitting device to emit light. It should be noted that the light-emitting device may be a mini light-emitting diode, a micro light-emitting diode, or an organic light-emitting diode.

In existing OLED display panels, because efficiency and turn-on voltages of red sub-pixels, green sub-pixels, and blue sub-pixels are different, the green sub-pixels are prone to a light leakage phenomenon under a black screen; under a high brightness screen, the blue sub-pixels do not easily reach preset brightness. Based on this, display quality of the existing OLED display panels is poor.

Compared with the prior art, in the OLED display panel provided by the embodiment of the present application, by differentially setting capacitors in the sub-pixel circuits that affect light emission of the light-emitting devices, the light leakage phenomenon of the green sub-pixels under a black screen is thus prevented; and/or, the blue sub-pixels can reach the preset brightness under the high brightness screen, so that the display quality of the OLED display panel can be improved.

Specifically, please refer to FIG. 1. FIG. 1 is a schematic circuit diagram of a sub-pixel circuit of an OLED display panel provided by an embodiment of the present application. As shown in FIG. 1, the sub-pixel circuit 10 includes a first transistor T1, a second transistor T2, a third transistor T3, a fourth transistor T4, a fifth transistor T5, a sixth transistor T6, a seventh transistor T7, a first capacitor C1, and a second capacitor C2. It should be noted that the sub-pixel circuit 10 may be the red sub-pixel circuit, the green sub-pixel circuit, or the blue sub-pixel circuit.

A gate of the first transistor T1 is electrically connected with a first node a, one of a source and a drain of the first transistor T1 is electrically connected with a second node b, and another one of the source and the drain of the first transistor T1 is electrically connected with a third node c. The first transistor T1 is configured to control currents flowing through a light-emitting device D.

A gate of the second transistor T2 is electrically connected with a first control signal terminal K1, one of a source and a drain of the second transistor T2 is electrically connected with a data signal terminal DD, and another one of the source and the drain of the second transistor T2 is electrically connected with the second node b. The second transistor T2 is configured to output signals received from the data signal terminal DD to the second node b under a control of signals received from the first control signal terminal K1.

A gate of the third transistor T3 is electrically connected with a second control signal terminal K2, one of a source and a drain of the third transistor T3 is electrically connected with the third node c, and another one of the source and the drain of the third transistor T3 is electrically connected with the first node a. The third transistor T3 is configured to conduct the third node c with the first node a under the control of signals received from the second control signal terminal K2.

A gate of the fourth transistor T4 is electrically connected with a third control signal terminal K3, one of a source and a drain of the fourth transistor T4 is electrically connected with a first power supply VDD, and another one of the source and the drain of the fourth transistor T4 is electrically connected with the second node b. The fourth transistor T4 is configured to output voltages supplied by the first power supply VDD to the second node b under the control of signals received from the third control signal terminal K3.

A gate of the fifth transistor T5 is electrically connected with the third control signal terminal K3, one of a source and a drain of the fifth transistor T5 is electrically connected with the third node c, i.e. connected to an anode of the light-emitting device D, and the other one of the source and the drain of the fifth transistor T5 is electrically connected with one of the source and the drain of the third transistor T1. A cathode of the light-emitting device D is electrically connected with a second power supply VSS. The fifth transistor T5 is configured to conduct the third node c with the anode of the light-emitting device D under the control of signals received from the third control signal terminal K3.

A gate of the sixth transistor T6 is electrically connected with a fourth control signal terminal K4, one of a source and a drain of the sixth transistor T6 is electrically connected with a first initialization power supply W1, and another one of the source and the drain of the sixth transistor T6 is electrically connected with the first node a.

A gate of the seventh transistor T7 is electrically connected with the first control signal terminal K1, one of a source and a drain of the seventh transistor T7 is electrically connected with a second initialization power supply W2, and the other one of the source and the drain of the seventh transistor T7 is electrically connected with the third node c, i.e. connected to the anode of the light-emitting device D. The seventh transistor T7 is configured to output voltages supplied by the second initialization power supply W2 to the anode of the light-emitting device D under the control of signals received from the first control signal terminal K1.

A first end of the first capacitor C1 is electrically connected with the first node a, and a second end of the first capacitor C1 is electrically connected with first control signal terminal K1.

A first end of the second capacitor C2 is electrically connected with the first power supply, and a second end of the second capacitor C2 is electrically connected with the first node a.

In the embodiment of the present application, both the first power supply VDD and the second power supply VSS are used to output a preset voltage value. In addition, in the embodiment of the present application, a voltage value output by the first power supply VDD is greater than a voltage value output by the second power supply VSS. Specifically, the voltage value output by the second power supply VSS may be a potential of a ground terminal. Of course, it can be understood that the voltage value output by the second power supply VSS can also be other.

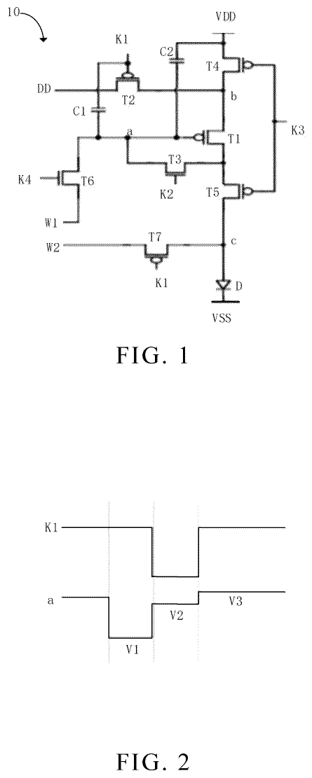

In the embodiment of the present application, a capacitor in the sub-pixel circuit 10 that affects the light emission of the light-emitting device D is the first capacitor C1. Specifically, please refer to FIG. 2. FIG. 2 is a schematic illustration diagram of the first capacitor affecting the light emission of the light-emitting device. How the first capacitor C1 affects the light-emitting device D to emit light will be described below in combination with FIG. 1 and FIG. 2.

In addition, the transistors used in the embodiment of the present application may include P-type transistors and/or N-type transistors. The P-type transistor is turned on when the gate is at low level, and turned off when the gate is at high level. The N-type transistor is turned on when the gate is at high level, and turned off when the gate is at low level. In the embodiment of the present application, the first transistor T1, the second transistor T2, the fourth transistor T4, the fifth transistor T5, and the seventh transistor T7 are all the P-type transistors. The third transistor T3 and the sixth transistor T6 are both the N-type transistors.

As shown in combination with FIG. 1 and FIG. 2, first, the sixth transistor T6 is turned on under the control of the signals received from the fourth control signal terminal K4, and a voltage supplied by the first initialization power supply W1 is output to the first node a via the sixth transistor T6, so that a potential of the first node a is the voltage supplied by the first initialization power supply W1. That is, at this time, a potential of the gate of the first transistor T1 is reset to the voltage supplied by the first initialization power supply W1, and at this time, the potential of the gate of the first transistor T1 is a first potential V1. At a same time, the first transistor T1 is turned on.

Next, the second transistor T2 is turned on under the control of the signals received from the first control signal terminal K1, and the third transistor T3 is turned on under the control of the signals received from the second control signal terminal K2, and the signals received from the data signal terminal DD is output to the first node a via the second transistor T2, the first transistor T1, and the third transistor T3, so that the signals received from the data signal terminal DD are written to the second capacitor C2. That is, at this time, the potential of the gate of the first transistor T1 is a second potential V2. It should be noted that at this time, a potential of the signals received from the first control signal terminal K1 is low potential.

Finally, the second transistor T2 is turned off under the control of the signals received from the first control signal terminal K1. That is, at this time, the potential of the signals received from the first control signal terminal K1 jumps from low potential to high potential. Since the first control signal terminal K1 is electrically connected with the second end of the first capacitor C1, when the signals received from the control signal terminal K1 jump from low potential to high potential, a potential at the second end of the first capacitor C1 also jumps from low potential to high potential. Due to a capacitive coupling effect, the potential of the second end of the first capacitor C1 will also be raised to a certain extent, so that the potential of the gate of the first transistor T1 is a third potential V3, and a magnitude of a current that drives the light-emitting device D to emit light is finally determined by the third potential V3. A magnitude of the third potential V3 is related to a capacitance value of the first capacitor C1.

Therefore, based on the different efficiency and turn-on voltages of the red sub-pixels, the green sub-pixels, and the blue sub-pixels, the embodiment of the present application can prevent the light leakage phenomenon of the green sub-pixels under the black screen by differentially setting the first capacitor C1 in the sub-pixel circuit 10 that affects the light emission of the light-emitting device D, and/or can make the blue sub-pixels reach the preset brightness under the high brightness screen, thereby improving the display quality of the OLED display panel. In the red sub-pixel circuits, the green sub-pixel circuits, and the blue sub-pixel circuits, a capacitance value of the first capacitor corresponding to the sub-pixel circuit of at least one color is different from a capacitance value of the first capacitor corresponding to the sub-pixel circuit of another one color.

A capacitance value of the first capacitor corresponding to the red sub-pixel circuit is less than or equal to a capacitance value of the first capacitor corresponding to the green sub-pixel circuit, and the capacitance value of the first capacitor corresponding to the red sub-pixel circuit is greater than or equal to a capacitance value of the first capacitor corresponding to the blue sub-pixel circuit.

That is, based on the light leakage phenomenon of the green sub-pixels in the black screen, the embodiment of the present application sets the capacitance value of the first capacitor C1 corresponding to the green sub-pixel circuit to a maximum value in the red sub-pixel circuit, the green sub-pixel circuit, and the blue sub-pixel circuit, so that the light leakage phenomenon of the green sub-pixels in the black screen can be prevented, thereby improving the display quality of the OLED display panel.

That is, based on that the blue sub-pixel fails to reach the preset brightness in the high brightness screen, the embodiment of the present application sets the capacitance value of the first capacitor C1 corresponding to the blue sub-pixel circuit to a minimum value in the red sub-pixel circuit, the green sub-pixel circuit, and the blue sub-pixel circuit, so that the blue sub-pixel can reach the preset brightness in the high brightness screen, thereby improving the display quality of the OLED display panel.

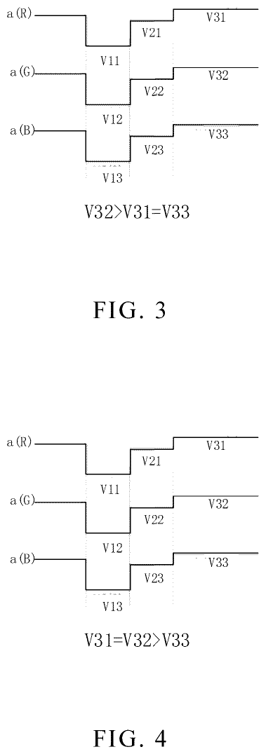

In one embodiment, in the red sub-pixel circuit, the green sub-pixel circuit, and the blue sub-pixel circuit, the capacitance value of the first capacitor C1 corresponding to the red sub-pixel circuit is equal to the capacitance value of the first capacitor C1 corresponding to the blue sub-pixel circuit, and the capacitance value of the first capacitor C1 corresponding to the green sub-pixel circuit is greatest. Please refer to FIG. 3, which is a first schematic illustration diagram of potentials of the first nodes corresponding to the red sub-pixel circuit, the green sub-pixel circuit, and the blue sub-pixel circuit in the OLED display panel provided by the embodiment of the present application. Combined with FIG. 1 and FIG. 4, since in the red sub-pixel circuit, the green sub-pixel circuit, and the blue sub-pixel circuit, the capacitance value of the first capacitor C1 corresponding to the red sub-pixel circuit is equal to the capacitance value of the first capacitor C1 corresponding to the blue sub-pixel circuit, and the capacitance value of the first capacitor C1 corresponding to the green sub-pixel circuit is greatest, so a third potential V31 of the first node a(R) corresponding to the red sub-pixel circuit is equal to a third potential V33 of the first node a(B) corresponding to the blue sub-pixel circuit, and a third potential V32 of the first node a(G) corresponding to the green sub-pixel circuit is relatively great, so that the light leakage phenomenon of the green sub-pixels under the black screen can be prevented, thereby improving the display quality of the OLED display panel.

In one embodiment, in the red sub-pixel circuit, the green sub-pixel circuit, and the blue sub-pixel circuit, the capacitance value of the first capacitor C1 corresponding to the red sub-pixel circuit is equal to the capacitance value of the first capacitor C1 corresponding to the green sub-pixel circuit, and the capacitance value of the first capacitor C1 corresponding to the blue sub-pixel circuit is least. Please refer to FIG. 4, which is a second schematic illustration diagram of the potentials of the first nodes corresponding to the red sub-pixel circuit, the green sub-pixel circuit, and the blue sub-pixel circuit in the OLED display panel provided by the embodiment of the present application. Combined with FIG. 1 and FIG. 4, since in the red sub-pixel circuit, the green sub-pixel circuit, and the blue sub-pixel circuit, the capacitance value of the first capacitor C1 corresponding to the red sub-pixel circuit is equal to the capacitance value of the first capacitor C1 corresponding to the green sub-pixel circuit, and the capacitance value of the first capacitor C1 corresponding to the blue sub-pixel circuit is least, so the third potential V31 of the first node a(R) corresponding to the red sub-pixel circuit is equal to the third potential V32 of the first node a(R) corresponding to the green sub-pixel circuit, and the third potential V33 of the first node a(B) corresponding to the blue sub-pixel circuit is relatively small, so that the blue sub-pixels can reach the preset brightness in the high brightness screen, thereby improving the display quality of the OLED display panel.

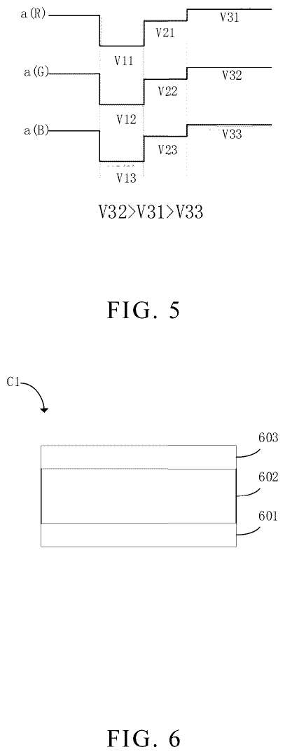

In one embodiment, in the red sub-pixel circuit, the green sub-pixel circuit, and the blue sub-pixel circuit, the capacitance value of the first capacitor C1 corresponding to the green sub-pixel circuit is greater than the capacitance value of the first capacitor C1 corresponding to the red sub-pixel circuit, and the capacitance value of the first capacitor C1 corresponding to the red sub-pixel circuit is greater than the capacitance value of the first capacitor C1 corresponding to the blue sub-pixel circuit. Please refer to FIG. 5, which is a third schematic illustration diagram of the potentials of the first nodes corresponding to the red sub-pixel circuit, the green sub-pixel circuit, and the blue sub-pixel circuit in the OLED display panel provided by the embodiment of the present application. Combined with FIG. 1 and FIG. 5, in the red sub-pixel circuit, the green sub-pixel circuit, and the blue sub-pixel circuit, the capacitance value of the first capacitor C1 corresponding to the green sub-pixel circuit is greater than the capacitance value of the first capacitor C1 corresponding to the red sub-pixel circuit, and the capacitance value of the capacitor C1 corresponding to the red sub-pixel circuit is greater than the capacitance value of the first capacitor C1 corresponding to the blue sub-pixel circuit, so the third potential V32 of the first node a(G) corresponding to the green sub-pixel circuit is greater than the third potential V31 of the first node a(R) corresponding to the red sub-pixel circuit, and the third potential value V31 of the first node a(R) corresponding to the red sub-pixel circuit is greater than the third potential value V33 of the first node a(B) corresponding to the blue sub-pixel circuit, and thus the light leakage phenomenon of the green sub-pixels in the black screen can be prevented, and the blue sub-pixels can reach the preset brightness in the high brightness screen, thereby improving the display quality of the OLED display panel.

Please refer to FIG. 6. FIG. 6 is a schematic structural diagram of the first capacitor in the sub-pixel circuit shown in FIG. 1. Combined with FIG. 1 and FIG. 6, the first capacitor C1 includes a first electrode plate 601, a second electrode plate 603, and a dielectric layer 602 disposed between the first electrode plate 601 and the second electrode plate 603. In the embodiment of the present application, an overlapping area of an orthographic projection of the first electrode plate 601 and an orthographic projection of the second electrode plate 603 in a thickness direction of the OLED display panel can be adjusted, or a thickness of the dielectric layer 602 can be adjusted, or a dielectric constant of the dielectric layer 602 can be adjusted, so that the capacitance value of the first capacitor C1 affecting the light emission of the light-emitting device D in the sub-pixel circuit 10 is set differently.

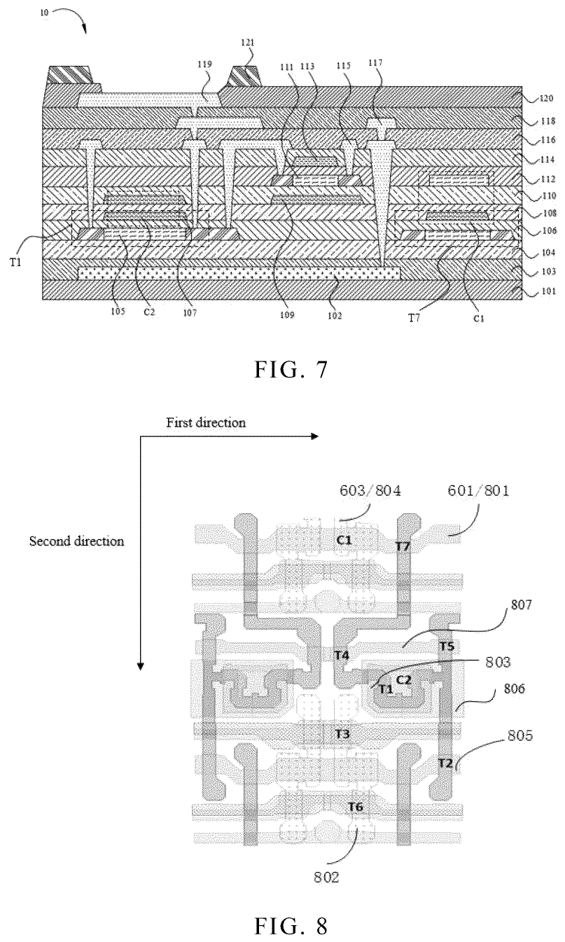

Specifically, please refer to FIG. 7, which is a schematic structural diagram of the OLED display panel provided by the embodiment of the present application. Combined with FIG. 6 and FIG. 7, the OLED display panel 100 includes a substrate 101, a light-shielding metal layer 102, a first buffer layer 103, a second buffer layer 104, a first conductive channel layer 105, a first insulating layer 106, a first gate layer 107, a second insulating layer 108, a second gate layer 109, a third insulating layer 110, a second conductive channel layer 111, a fourth insulating layer 112, a third gate layer 113, a fifth insulating layer 114, a source and drain layer 115, a sixth insulating layer 116, a connection layer 117, a seventh insulating layer 118, an anode layer 119, a pixel definition layer 120, and a PS layer 121 stacked in sequence. The connection layer 117 electrically connects the anode layer 119 and the source and drain layer 115. The light-shielding metal layer 102, the first conductive channel layer 105, the first gate layer 107, the second gate layer 109, the second conductive channel layer 111, the third gate layer 113, the source and drain layer 115, and the connection layer 117 are all metal layers and together form a driving circuit layer, which includes the above-mentioned sub-pixel circuits. The first buffer layer 103, the second buffer layer 104, the first insulating layer 106, a first gate layer 107, the second insulating layer 108, the third insulating layer 110, the fourth insulating layer 112, the fifth insulating layer 114, and the sixth insulating layer 116 are insulating films and together form an insulating film structure for isolating adjacent metal layers in the thickness direction of the OLED display panel.

The first gate layer 107 includes a gate (such as a gate of the above-mentioned first transistor T1, a gate of the above-mentioned second transistor T2, a gate of the above-mentioned fourth transistor T4, a gate of the above-mentioned fifth transistor T5, or a gate of the above-mentioned seventh transistor T7) and the first electrode plate (such as the first electrode plate of the first capacitor C1 and the first end of the second capacitor C2), the dielectric layer includes the second insulating layer 108 and the third insulating layer 110, and the second conductive channel layer 111 includes conductive channels (such as active layers of the third transistor T3 and the sixth transistor T6) and the second electrode plate of the first capacitor C1.

An overlapping area of the orthographic projections of the first electrode plate and the second electrode plate corresponding to the first capacitor C1 of the sub-pixel circuit of at least one color on the substrate 101 is different from an overlapping area of the orthographic projections of the first electrode plate and the second electrode plate of the sub-pixel circuit of another one color on the substrate 101.

An overlapping area of the orthographic projections of the first electrode plate and the second electrode plate corresponding to the first capacitor C1 corresponding to the red sub-pixel circuit on the substrate 101 is less than or equal to an overlapping area of the orthographic projections of the first electrode plate and the second electrode plate corresponding to the first capacitor C1 corresponding to the green sub-pixel circuit on the substrate 101. The overlapping area of the orthographic projections of the first electrode plate and the second electrode plate corresponding to the first capacitor C1 corresponding to the red sub-pixel circuit on the substrate 101 is greater than or equal to an overlapping area of the orthographic projections of the first electrode plate and the second electrode plate corresponding to the first capacitor C1 corresponding to the blue sub-pixel circuit on the substrate 101.

For example, line widths of the first electrode plate and the second electrode plate corresponding to the first capacitor C1 corresponding to the red sub-pixel circuit are less than or equal to line widths of the first electrode plate and the second electrode plate corresponding to the first capacitor C1 corresponding to the green sub-pixel circuit. The line widths of the first electrode plate and the second electrode plate corresponding to the first capacitor C1 corresponding to the red sub-pixel circuit are greater than or equal to line widths of the first electrode plate and the second electrode plate corresponding to the first capacitor C1 corresponding to the blue sub-pixel circuit.

Further, please refer to FIG. 8. FIG. 8 is a schematic diagram of wiring of the sub-pixel circuit shown in FIG. 1. As illustrated in FIG. 7 and FIG. 8, in the embodiments, the first transistor T1, the second transistor T2, the fourth transistor T4, the fifth transistor T5, and the seventh transistor T7 are provided to have a single-gate structure, and the third transistor T3 and the sixth transistor T6 are provided to have a double-gate structure. Active layers of the first transistor T1, the second transistor T2, the fourth transistor T4, the fifth transistor T5, and the seventh transistor T7 are arranged in a same metal layer, and the gates of first transistor T1, the second transistor T2, the fourth transistor T4, the fifth transistor T5, and the seventh transistor T7 are arranged in a same metal layer. Active layers of the third transistor T3 and the sixth transistor T6 are arranged in a same metal layer, one gate of the third transistor T3 and one gate of the sixth transistor T6 are arranged in a same metal layer, and the other gate of the third transistor T3 and the other gate of the sixth transistor T6 are arranged in a same metal layer. Combined with FIG. 1, FIG. 7, and FIG. 8, the first electrode plate 601 extends along a first direction, the second electrode plate 603 extends along a second direction, and the first direction intersects with the second direction. Both the first electrode plate 601 and the gate of the seventh transistor T7 are arranged in a first electrode block 801, which is a part of the first gate layer 107. The active layers of the third transistor T3 and the sixth transistor T6 are arranged in a second electrode block 802, which extends along the second direction. The gate of the first transistor T1 and the first end of the second capacitor C2 are arranged in a third electrode block 803 provided in the same metal layer as the first electrode block 801. The second electrode plate 603 is arranged in a fourth electrode block 804 provided in the same metal layer as the second electrode block 802, and the fourth electrode block 804 and the second electrode blocks 802 are parts of the second conductive channel layer 111. The gate of the second transistor T2 is arranged in a fifth electrode block 805 provided in the same metal layer as the first electrode block 801, and the fifth electrode block 805, the third electrode block 803, and the first electrode block 801 are parts of the first gate layer 107. The second end of the second capacitor C2 is a sixth electrode block 806, which is a part of the second gate layer 109. The gate of the fourth transistor T4 and the gate of the fifth transistor T5 are arranged in a seventh electrode block 807, which extends along the first direction and is a part of the first gate layer 107. The above-mentioned electrode blocks are individual electrode blocks.

The first electrode block 801 is electrically connected with the fifth electrode block 805, and the second electrode block 802, the third electrode block 803, and the fourth electrode block 804 are electrically connected. The first electrode block 801 and the fifth electrode block 805 are disposed at interval along the first direction, and the fourth electrode block 804 and the second electrode block 802 are disposed at interval along the first direction. The second electrode block 802 has a same shape as the fourth electrode block 804.

Specifically, in the embodiment of the present application, an overlapping area of the first electrode block 801 and the fourth electrode block can be adjusted, so that the capacitance values of the first capacitors C1 corresponding to different sub-pixels are different. That is, in the red sub-pixel circuit, the green sub-pixel circuit, and the blue sub-pixel circuit, the capacitance value of the first capacitor corresponding to the sub-pixel circuit of at least one color is different from the capacitance value of the first capacitor corresponding to the sub-pixel circuit of another one color, so that the capacitance value of the first capacitor corresponding to the green sub-pixel circuit is greatest; and/or, in the red sub-pixel circuit, the green sub-pixel circuit, and the blue sub-pixel circuit, the capacitance value of the first capacitor corresponding to the blue sub-pixel circuit is least, so as to prevent the light leakage phenomenon of the green sub-pixels under the black screen, and/or the blue sub-pixels can be made to reach the preset brightness in the high brightness screen, thereby improving the display quality of the OLED display panel.

The thickness of the dielectric layer 602 corresponding to the first capacitor C1 of the sub-pixel circuit of at least one color is different from the thickness of the dielectric layer 602 corresponding to the first capacitor C1 of the sub-pixel circuit of another one color.

For example, a thickness of the dielectric layer 602 corresponding to the first capacitor C1 corresponding to the red sub-pixel circuit is greater than or equal to a thickness of the dielectric layer 602 corresponding to the first capacitor C1 corresponding to the green sub-pixel circuit. The thickness of the dielectric layer 602 corresponding to the first capacitor C1 corresponding to the red sub-pixel circuit is less than or equal to a thickness of the dielectric layer 602 corresponding to the first capacitor C1 corresponding to the blue sub-pixel circuit.

The dielectric constant of the dielectric layer 602 corresponding to the first capacitor C1 corresponding to the sub-pixel circuit of at least one color is different from the dielectric constant of the dielectric layer 602 corresponding to the sub-pixel circuit of another one color.

For example, a dielectric constant of the dielectric layer 602 corresponding to the first capacitor C1 corresponding to the red sub-pixel circuit is less than or equal to a dielectric constant of the dielectric layer 602 corresponding to the first capacitor C1 corresponding to the green sub-pixel circuit. The dielectric constant of the dielectric layer 602 corresponding to the first capacitor C1 corresponding to the red sub-pixel circuit is greater than or equal to a dielectric constant of the dielectric layer 602 corresponding to the first capacitor C1 corresponding to the blue sub-pixel circuit.

In the OLED display panel provided by the present application, the capacitance value of the first capacitor C1 corresponding to the green sub-pixel circuit is greatest in the red sub-pixel circuit, the green sub-pixel circuit, and the blue sub-pixel circuit, and/or in the red sub-pixel circuit, the green sub-pixel circuit, and the blue sub-pixel circuit, the capacitance value of the first capacitor C1 corresponding to the blue sub-pixel circuit is least, so that the green sub-pixels are prevented from the light leakage phenomenon in the black screen, and/or the blue sub-pixel can be made to reach the preset brightness in the high brightness screen, thereby improving the display quality of the OLED display panel.

The principles and implementations of the present application are described herein using specific examples, and the descriptions of the above embodiments are only used to help understand the methods and core ideas of the present application; meanwhile, for those skilled in the art, according to the thoughts, there will be changes in specific embodiments and application scopes. To sum up, the contents of this specification should not be construed as limitation of the present invention.

What is claimed is:

1. An organic light emitting diode (OLED) display panel, comprising:
a substrate; and
a driving circuit layer disposed on the substrate and comprising a plurality of sub-pixel circuits configured to drive a light-emitting device to emit light,
wherein the plurality of sub-pixel circuits comprise a red sub-pixel circuit, a green sub-pixel circuit, and a blue sub-pixel circuit, and each of the red sub-pixel circuit, the green sub-pixel circuit, and the blue sub-pixel circuit comprises a first transistor configured to control a current flowing through the light-emitting device, a second transistor, a first capacitor, and a second first capacitor;
wherein the driving circuit layer comprises:
a first conductive channel layer disposed on the substrate, and comprising:
an active layer of the first transistor; and
an active layer of the second transistor;
a first gate layer disposed on one side of the first conductive channel layer facing away from the substrate, and comprising:
a gate of the first transistor;
a gate of the second transistor electrically connected with a first control signal terminal;
a first electrode plate of the first capacitor electrically connected with the gate of the first transistor; and
a first end of the second capacitor electrically connected with a first power supply;
a second gate layer disposed on one side of the first gate layer facing away from the substrate, and comprising:
a second end of the second capacitor electrically connected with the gate of the first transistor;
a second conductive channel layer disposed on one side of the second gate layer facing away from the substrate, and comprising:
a second electrode plate of the first capacitor electrically connected with the first control signal terminal; and
a source and drain layer disposed on one side of the first gate layer facing away from the substrate, and comprising:
a source and a drain of the first transistor electrically connected with the active layer of the first transistor; and
a source and a drain of the second transistor electrically connected with the active layer of the second transistor, wherein one of the source and the drain of the second transistor is electrically connected with a data signal terminal, and the other one of the source and the drain of the second transistor is electrically connected with one of the source and the drain of the first transistor; and
wherein a capacitance value of the first capacitor corresponding to one of the sub-pixel circuits of at least one color is different from a capacitance value of the first capacitor corresponding to another one of the sub-pixel circuits of another one color.

2. The OLED display panel according to claim 1, wherein in a thickness direction of the OLED display panel, an overlapping area of orthographic projections of the first electrode plate and the second electrode plate of the first capacitor corresponding to the one of the sub-pixel circuits of at least one color is different from an overlapping area of orthographic projections of the first electrode plate and the second electrode plate of the first capacitor corresponding to the another one of the sub-pixel circuits of another one color.

3. The OLED display panel according to claim 1, wherein the first capacitor comprises a dielectric layer disposed between the first electrode plate and the second electrode plate, and a thickness of the dielectric layer of the first capacitor corresponding to the one of the sub-pixel circuits of at least one color is different from a thickness of the dielectric layer of the first capacitor corresponding to the another one of the sub-pixel circuits of another one color.

4. The OLED display panel according to claim 1, wherein the first capacitor comprises a dielectric layer disposed between the first electrode plate and the second electrode plate, and a dielectric constant of the dielectric layer of the first capacitor corresponding to the one of the sub-pixel circuits of at least one color is different from a dielectric constant of the dielectric layer of the first capacitor corresponding to the another one of the sub-pixel circuits of another one color.

5. The OLED display panel according to claim 1, wherein a capacitance value of the first capacitor corresponding to the red sub-pixel circuit is less than or equal to a capacitance value of the first capacitor corresponding to the green sub-pixel circuit, and the capacitance value of the first capacitor corresponding to the red sub-pixel circuit is greater than or equal to a capacitance value of the first capacitor corresponding to the blue sub-pixel circuit.

6. The OLED display panel according to claim 1, wherein each of the red sub-pixel circuit, the green sub-pixel circuit, and the blue sub-pixel circuit further comprises a third transistor, a fourth transistor, a fifth transistor, a sixth transistor, and a seventh transistor;
the first conductive channel layer further comprises:
an active layer of the fourth transistor;
an active layer of the fifth transistor; and
an active layer of the seventh transistor;
the first gate layer further comprises:
a gate of the fourth transistor electrically connected with a third control signal terminal;
a gate of the fifth transistor electrically connected with the third control signal terminal; and
a gate of the seventh transistor electrically connected with the first control signal terminal;
the second conductive channel layer further comprises:
an active layer of the third transistor; and
an active layer of the sixth transistor;
the driving circuit layer further comprises a third gate layer, and the second gate layer and the third gate layer comprise:
a gate of the third transistor electrically connected with a second control signal terminal; and
a gate of the sixth transistor electrically connected with a fourth control signal terminal; and
the source and drain layer further comprises:
a source and a drain of the third transistor electrically connected with the active layer of the third transistor, wherein one of the source and the drain of the third transistor is electrically connected with the gate of the first transistor, and the other one of the source and the drain of the third transistor is electrically connected with the other one of the source and the drain of the first transistor;
a source and a drain of the fourth transistor electrically connected with the active layer of the fourth transistor, wherein one of the source and the drain of the fourth transistor is electrically connected with the first power supply, and the other one of the source and the drain of the fourth transistor is electrically connected with the one of the source and the drain of the first transistor;
a source and a drain of the fifth transistor electrically connected with the active layer of the fifth transistor, wherein one of the source and the drain of the fifth transistor is electrically connected with the other one of the source and the drain of the first transistor, the other one of the source and the drain of the fifth transistor is electrically connected with an anode of the light-emitting device, and a cathode of the light-emitting device is electrically connected with a second power supply;
a source and a drain of the sixth transistor electrically connected with the active layer of the sixth transistor, wherein one of the source and the drain of the sixth transistor is electrically connected with a first initialization power supply, and the other one of the source and the drain of the sixth transistor is electrically connected with the gate of the first transistor; and
a source and a drain of the seventh transistor electrically connected with the active layer of the seventh transistor, wherein one of the source and the drain of the seventh transistor is electrically connected with a second initialization power supply, and the other one of the source and the drain of the seventh transistor is electrically connected with the anode of the light-emitting device.

7. The OLED display panel according to claim 6, wherein the first gate layer comprises a first electrode block extending in a first direction, the second conductive channel layer comprise a fourth electrode block extending in a second direction, the first direction intersects with the second direction; and
the first electrode block serves as the first electrode plate and the gate of the seventh transistor, and the fourth electrode block serves as the second electrode plate.

8. The OLED display panel according to claim 7, wherein the second conductive channel layer further comprise a second electrode block extending along the second direction, and the second electrode block servers as the active layer of the third transistor and the active layer of the sixth transistor.

9. The OLED display panel according to claim 7, wherein the first gate layer further comprises a third electrode block separated from the first electrode block, and the third electrode block serves as the gate of the first transistor and the first end of the second capacitor.

10. The OLED display panel according to claim 9, wherein the second gate layer comprises a sixth electrode block, and the sixth electrode block serves as the second end of the second capacitor.

11. The OLED display panel according to claim 7, wherein the first gate layer further comprises a fifth electrode block separated from the first electrode block, and the fifth electrode block serves as the gate of the second transistor.

12. The OLED display panel according to claim 7, wherein the first gate layer further comprises a seventh electrode block extending along the first direction and separated from the first electrode block, and the seventh electrode block serves as the gate of the fourth transistor and the gate of the fifth transistor.

13. The OLED display panel according to claim 1, wherein the driving circuit layer further comprises a light-shielding metal layer disposed on the substrate and disposed on one side of the first conductive channel layer facing the substrate.

14. The OLED display panel according to claim 1, wherein the driving circuit layer further comprises a connection layer disposed on one side of the source and drain layer away from the substrate, and the connection layer electrically connects an anode of the light-emitting device and the source and drain layer.

15. The OLED display panel according to claim 1, further comprises an insulating film structure, wherein the insulating film structure is disposed between adjacent metal layers of the driving circuit layer in a thickness direction of the OLED display panel.

16. The OLED display panel according to claim 15, wherein the insulating film structure comprises two insulating layers between the first electrode plate and the second electrode plate, and the two insulating layers serve as a dielectric layer of the first capacitor.

17. An OLED display panel, comprising:
a substrate;
a first conductive channel layer disposed on the substrate, and comprising an active layer of a first transistor and an active layer of a second transistor;
a first gate layer disposed on one side of the first conductive channel layer facing away from the substrate, and comprising a gate of the first transistor, a gate of the second transistor, a first electrode plate of a first capacitor, and a first end of the second capacitor;
a second gate layer disposed on one side of the first gate layer facing away from the substrate, and comprising a second end of the second capacitor;
a second conductive channel layer disposed on one side of the second gate layer facing away from the substrate, and comprising a second electrode plate of the first capacitor;
a source and drain layer disposed on one side of the first gate layer facing away from the substrate, and comprising a source and a drain of the first transistor, and a source and a drain of the second transistor; and
a light emitting device disposed on one side of the source and drain layer facing away from the substrate,
wherein the first transistor is configured to control a current flowing through the light-emitting device.
